(19) United States
(12) Patent Application Publication
(10) Pub. No.: US 2009/0111726 A1
(43) Pub. Date: Apr. 30, 2009

(54) Compounds for Photoresist Stripping

(76) Inventor: X. Cass Shang, Sunnyvale, CA (US)

Correspondence Address: MORGAN LEWIS & BOCKIUS LLP, 1111 PENNSYLVANIA AVENUE NW, WASHINGTON, DC, 20004, US

(21) Appl. No.: 12/239,923

(22) Filed: Sep. 29, 2008

Related U.S. Application Data
(60) Provisional application No. 61/001,053, filed on Oct. 31, 2007.

(51) Int. Cl. G03F 7/42

(52) U.S. Cl. 510/176

(57) ABSTRACT

A composition for removing undesired matter from a substrate, the composition comprising hydroxylamine or a hydroxylamine derivative, a quaternary ammonium compound and at least one polar organic solvent. The composition is capable of removing photoresist from wafer level packaging and solder bumping applications.

The present application claims the benefit of U.S. Provisional Application No. 61/001,053, filed Oct. 31, 2007, which is hereby incorporated by reference in its entirety.

### BACKGROUND OF THE INVENTION

1. Field of the Invention

This invention relates generally to a cleaning composition for removing photoresist polymer from a substrate comprising metal and/or metal alloy portions and layers. The invention is useful for stripping photoresist polymer (including, but not limited to, ion-implanted photoresist) in wafer level packaging and solder bumping processes.

2. Description of Related Art

The manufacture of semiconductor integrated circuits typically involves highly complex, time-consuming and costly processes which, with continually narrower line width requirements, must be achieved with an ever increasing degree of precision. During the manufacture of the semiconductor and semiconductor microcircuits, it is necessary to coat the substrates from which the semiconductors and microcircuits are made with a polymeric organic film, generally referred to as a photoresist, e.g., a substance which forms a patterned image upon exposure to light and developing. These types of photoresist are used to protect selected areas of the surface of the substrate while processes such as etching is to delineate a pattern to the substrate and also used as doping mask during ion implantation steps.

In the manufacture of integrated circuits, the process steps include coating onto the surfaces of semiconductor substrates materials such as metals to define the circuitry, dielectrics as insulators and organic polymeric materials to protect the circuit patterns in the electronic component. The substrate is typically an SiO₂ dielectric covered silicon wafer and contains metallic microcircuitry such as aluminum or aluminum alloys in and/or on the dielectric surface.

Basically, the fabrication of integrated circuits utilizes a photoresist composition which generally comprises a polymeric resin, a radiation sensitive compound and a suitable solvent to enable forming a film of the photoresist over a particular substrate for photolithographically delineating patterns on such substrates. In a typical processing scheme, the photoresist compositions are spun on or applied to the substrate using methods known in the art. Then the photoresist compositions are typically subjected to a pre-exposure bake to drive off a portion of the solvent to impart dimensional stability to the film. The coated substrate is selectively exposed with radiation such as UV, e-beam or x-ray spectra through a patterning mask using an appropriate exposure tool for such exposure. After exposure, the coated substrate undergoes a development process where, due to selective dissolution of certain areas, a pattern is formed or developed. In certain areas of the photoresist film, the photoresist material is completely removed, whereas in the other areas the remaining photoresist forms a pattern having a desired or intended configuration. Such patterns are used-to mask or protect the substrate for subsequent wet or dry etching processes, the deposit of conductor or insulative patterns, or for incorporation of the pattern photoresist into the device or package as, for example, an insulating or dielectric layer.

In one fabrication process for an integrated circuit, a top coating can be applied to the integrated circuit. Typically, a polymer layer is applied to the top surface of the integrated circuit and developed to expose pads on the surface of the integrated circuit device. The polymer is then cured and an interconnect is made through the surface of the integrated circuit device.

Polyimides are increasingly being used in integrated circuit manufacture. The use of a polyimide as a fabrication aid includes application of the polyimide as a photoresist, planarization layer and insulator. In these applications, the polymers are applied to a wafer substrate and subsequently cured in the desired pattern by a suitable method. When the polyimide is used as a seal or a top coat, the polyimide layer is not removed except for the areas over the pads and remains on the surface of the semiconductor device.

Semiconductor devices are very expensive, and if there is a defect in the device, it is highly desirable to be able to repair the device. To repair (typically termed “rework”) the device, it is necessary to remove coatings such as polyimides, epoxies and the like and it is essential that the underlying metallization of the device not be adversely affected by the stripping composition.

Many formulations have been developed to remove both positive and negative resist. A resist includes polymeric material, which may be crosslinked or hardened by baking. Therefore, a simple combination of solvents will often remove resists, though time and temperature constraints in the manufacturing process have in general moved the industry to slightly more aggressive compounds.

Early compositions used for removing photoresists and other substrate layers have, for the most part, been highly flammable. In addition, reactive solvent mixtures can exhibit an undesirable degree of toxicity and are generally hazardous to both humans and the environment. Moreover, these compositions are not only toxic, but their disposal is costly, since they must be disposed of as a hazardous waste. In addition, these prior art compositions generally have a severely limited bath life and, for the most part, are-not recyclable or reusable.

Fluoride containing chemistries have been used for many years to clean prime silicon wafers (wafers that have not yet undergone ion implantation or device construction) in the semiconductor industry. Normally the fluoride chemistry (usually dilute hydrofluoric acid) is used as the last process step in the sequence called “RCA rinses”. The substrate is often contaminated from previous process steps with monolayer amounts of metal, anions and/or organic contaminants or surface residues (particles). These contaminants have been shown to have significant impact on the electrical integrity of simple test device structures, and they need to be efficiently cleaned without impairing their integrity. Such cleaning methods could include techniques discussed in the technical literature, for example, Int. Conf. On Solid State Devices and Materials, 1991, pp. 484-486 or Kujime, T. et al., Proc. of the 1996 Semi. Pure Water and Chemicals, pp. 245-256 and Singer, P. Semi. International, p. 88, October 1995.

Patents that teach methods for cleaning prime wafers with low pH solutions include U.S. Pat. Nos. 5,560,857 and 5,645,737; 5,181,985; 5,603,849; 5,705,089.

Cleaning compositions used for removing photoresist coatings not already ashed and other substrates have, for the most part, been highly flammable, generally hazardous to both humans and the environment, and comprise reactive solvent mixtures exhibiting an undesirable degree of toxicity. Moreover, these cleaning compositions are not only toxic, but their disposal is costly since they might have to be disposed of as a hazardous waste. In addition, these compositions generally have severely limited bath life and, for the most part, are not recyclable or reusable.

An additional problem is the removal of ion implanted photoresist. Complete removal of photoresist which has been exposed to high-dose, ion implant in excess of 1×10¹⁵ atoms/cm² is usually a problem for conventional stripping and cleaning methods such as plasma ashing. The high-dose ion implant treatment results in the formation of a tough, carbonized crust which protects the underlying bulk photoresist from the cleaning process.

Conventional methods of cleaning require an oxygen-plasma ash, often in combination with halogen gases, to penetrate the crust and remove the photoresist. Usually, the plasma ashing process also requires a follow-up cleaning with wet-chemicals and acids to remove the residues and non-volatile contaminants that remain after ashing. Despite this treatment, it is not unusual to repeat the “ash plus wet-clean” cycle in order to completely remove all photoresist and residues.

Some of the problems that arise from using from these conventional processes include:

popping of the photoresist (and the resulting contamination) as heated, residual solvent in the bulk photoresist vaporizes under the hardened crust;

gate oxide erosion and line-lifting from the use of halogen gases during cleaning;,

residual metal contamination due to the presence of non-volatile metal compounds in the photoresist which are not removed by the plasma ashing process;

tough residues remaining despite the use of plasma ashing and wet chemical treatments; and

repetitive cleaning steps which increase photoresist stripping cycle times and work-in-process.

Accordingly, there exists a need to develop improved cleaning compositions to efficiently remove undesired subject matter from a substrate, including removing photoresist from a substrate. Particularly in the field of integrated circuit fabrication, it should be recognized that the demands for improved cleaning performance with avoidance of attack on the substrates being cleaned are constantly increasing. This means that compositions that were suitable for cleaning and removing less sophisticated integrated circuit substrates may not be able to produce satisfactory results with substrates containing more advanced integrated circuits in the process of fabrication. For example, there exists a need to provide a semiconductor cleaning substrate that is effective at low temperatures (less than about 65° C.). There also exists a need to provide a composition that can prolong the bath life and provide a shorter processing time, as well as a composition that saves the customer energy costs, and reduces safety and environmental compliance concerns. There also exists a need to provide a composition that removes polyimide, cured polyimide, epoxy photoresist, hardened photoresist, ion implanted photoresist or other polymers from a substrate comprising metal and/or metal alloy portions and/or layers. And more specifically, there exists a need to strip or remove photoresist from the wafer level packaging and solder bumping process steps.

### SUMMARY OF THE INVENTION

The novel cleaning compositions of the invention exhibit synergistically enhanced cleaning action and cleaning capabilities at low temperatures to dissolve unexposed photoresist from the substrate and to strip ion implanted photoresist.

It is a general object of the invention to provide a semiconductor cleaning substrate that is effective at low temperatures (less than about 65° C.).

It is a further object of the invention to provide a post etch residue cleaning composition that dissolves photoresist polymer, including unexposed photoresist polymer, and strips ion implanted photoresist polymer.

It is a further object of the invention to provide a composition that can prolong the bath life and provide a shorter processing time.

It is a further object of the invention to provide a post etch residue cleaning composition that saves the customer energy costs, and reduces safety and environmental compliance concerns.

Broadly stated, the objects of the invention are realized, according to one aspect of the invention, through use of a composition that includes hydroxylamine or a hydroxylamine derivative, a quaternary ammonium compound and at least one polar organic solvent. The composition is capable of removing undesired material from a substrate, including, but not limited to, polyimide, cured polyimide, epoxy photoresist, hardened photoresist, liquid or dry film resist, ion implanted photoresist or other polymers. More particularly, the composition is capable of removing photoresist from wafer level packaging and solder bumping process applications.

The substrate can comprise metal and/or metal alloy portions and/or layers. It can further comprise metals under bump metallurgy (including, but not limited to, Cu, Cr, Au, Ti, W, TiW, TiWN, Ta, TaN, Ni, NiV or mixtures thereof), solder bump metals (including, but not limited to, Pb, Sn, Pb/Sn, Sn/Ag, Sn/Cu/Ag, Au, Ag, Cu, Ni) and metal pad metals (including, Al and Cu).

The invention is based in part on the finding that the use of quaternary ammonium compounds which contain a hydroxyl group and, optionally, at least one polar organic solvent which enhances the ability of the composition to dissolve the photo resist polymer. Moreover, the use of hydroxylamine or a hydroxylamine derivative in this composition unexpectedly appears to stabilize the quaternary ammonium compound and therefore prolongs the bath and shelf life of the composition.

According to one aspect of the invention, it appears that the use of at least one quaternary ammonium compound forms compositions that have a stable copper etch rate over time. It also appears that the use of at least one polar organic solvent together with at least one quaternary ammonium compound forms compositions that are even more likely to have a stable copper etch rate over time.

In certain embodiments, the quaternary ammonium compound is a member of the group consisting of tetramethylammonium hydroxide (TMAH), including TMAH pentahydrate; benzyltetramethylammonium hydroxide (BTMAH); tetrabutylammonium hydroxide (TBAH); choline hydroxide; and tris(2-hydroxyethyl)methylammonium hydroxide (THEMAH); quaternary ammonium hydroxide and mixtures thereof. A preferred quaternary ammonium compound is TMAH.

In certain embodiments, the at least one polar organic solvent can comprise one or more sulfones, sulfoxides, pyrolidones or a mixtures thereof. A preferred polar organic solvent is dimethyl sulfoxide (DMSO). In other embodiments, the composition can comprise at least two polar organic solvents.

In another embodiment, the hydroxylamine or hydroxylamine derivative is hydroxylamine, the quaternary ammonium compound is TMAH and the at least one polar organic solvent comprises DMSO. In another aspect of the invention, the hydroxylamine or a hydroxylamine derivative is N,N diethyl hydroxylamine.

In another aspect of the invention, the undesired matter comprises polyimide, cured polyimide, epoxy photoresist, hardened photoresist, liquid or dry film resist, ion implanted photoresist or other polymers from a substrate including metal and/or metal alloy portions and/or layers. In certain aspects, the metal and/or metal alloy can comprise copper, aluminum, lead, silver, tine, lead/tin or Ni. In another aspect, the metal and/or metal alloy can include one or more solder bumps.

In another embodiment, the composition of the invention comprises from about 1 to about 10% by weight of the hydroxylamine or hydroxylamine derivative, from about 10 to about 30% by weight of the quaternary ammonium compound and from about 50 to about 85% by weight of the at least one polar organic solvent. In this composition, the quaternary ammonium compound is present in about 25% in water. The hydroxylamine or hydroxylamine derivative in this compositional embodiment, as well as most of the compositional embodiments of the invention, is present in about 50% in water.

In another embodiment, the above compositions further comprise a corrosion inhibitor.

In various aspects of the invention, the hydroxylamine or hydroxylamine derivative can be hydroxylamine, the quaternary ammonium compound can be TMAH and the at least one polar organic solvent can include DMSO.

In other embodiments, the invention relates to a process for removing undesired matter from a substrate, the process comprising contacting the substrate with one of the above compositions for a period of time and at a temperature sufficient to remove the undesired matter from the substrate.

### BRIEF DESCRIPTION OF THE DRAWINGS

In order to facilitate a fuller understanding of the present disclosure, reference is now made to the accompanying drawings. These drawings should not be construed as limiting the present disclosure, but are intended to be exemplary only.

FIGS. 1-14 are scanning electron microscope (SEM) photographs showing comparative results achieved using selected embodiments of compositions and processes of the present invention, as described in the examples herein.

FIG. 1A shows an SEM observation of a eutectic Pb/Sn solder bump patterned with DuPont WBR-E Dry Film Resist at center of the wafer before stripping.

FIG. 1B shows an SEM observation of a eutectic Pb/Sn solder bump patterned with DuPont WBR-E Dry Film Resist at edge of the wafer before stripping.

FIG. 2A shows an SEM observation at 500× magnification of a eutectic Pb/Sn solder bump patterned with DuPont WBR-E Dry Film Resist. The photoresist has been removed by EKC108 at 55° C. for 20 minutes.

FIG. 2B shows an SEM observation at 1000× magnification of a eutectic Pb/Sn solder bump patterned with DuPont WBR-E Dry Film Resist. The photoresist has been removed by EKC108 at 55° C. for 20 minutes.

FIG. 3A shows an SEM observation at 500× magnification of a eutectic Pb/Sn solder bump patterned with DuPont WBR-E Dry Film Resist. The photoresist has been removed by CSX-W62 (Composition 62) at 55° C. for 20 minutes.

FIG. 3B shows an SEM observation at 1000× magnification of a eutectic Pb/Sn solder bump patterned with DuPont WBR-E Dry Film Resist. The photoresist has been removed by CSX-W62 (Composition 62) at 55° C. for 20 minutes.

FIG. 4A shows an SEM observation at 500× magnification of a eutectic Pb/Sn solder bump patterned with DuPont WBR-E Dry Film Resist. The photoresist has been removed by CSX-W62B (Composition 62B) at 55° C. for 20 minutes.

FIG. 4B shows an SEM observation at 1000× magnification of a eutectic Pb/Sn solder bump patterned with DuPont WBR-E Dry Film Resist. The photoresist has been removed by CSX-W62B (Composition 62B) at 55° C. for 20 minutes.

FIG. 5A shows a SEM observation of at 500× magnification of a eutectic Pb/Sn solder bump patterned with DuPont WBR-E Dry Film Resist. The photoresist has been removed by CSX-W62C (Composition 62C) at 55° C. for 20 minutes.

FIG. 5B shows an SEM observation at 2500× magnification of a eutectic Pb/Sn solder bump patterned with DuPont WBR-E Dry Film Resist. The photoresist has been removed by CSX-W62C (Composition 62C) at 55° C. for 20 minutes.

FIG. 6A shows a SEM observation at 500× magnification of a eutectic Pb/Sn solder bump patterned with DuPont WBR-E Dry Film Resist. The photoresist has been removed by CSX-W70 (Composition 70) at 55° C. for 20 minutes.

FIG. 6B shows a SEM observation at 2500× magnification of a eutectic Pb/Sn solder bump patterned with DuPont WBR-E Dry Film Resist. The photoresist has been removed by CSX-W70 (Composition 70) at 55° C. for 20 minutes.

FIG. 7A shows an SEM observation at 500× magnification of a eutectic Pb/Sn solder bump patterned with DuPont WBR-E Dry Film Resist. The photoresist has been removed by CSX-W72 (Composition 72) at 55° C. for 20 minutes.

FIG. 7B shows an SEM observation at 2500× magnification of a eutectic Pb/Sn solder bump patterned with DuPont WBR-E Dry Film Resist. The photoresist has been removed by CSX-W72 (Composition 72) at 55° C. for 20 minutes.

FIG. 8A shows an SEM observation at 500× magnification of a eutectic Pb/Sn solder bump patterned with DuPont WBR-E Dry Film Resist. The photoresist has been removed by CSX-W73 (Composition 73) at 55° C. for 20 minutes

FIG. 8B shows an SEM observation at 2500× magnification of a eutectic Pb/Sn solder bump patterned with DuPont WBR-E Dry Film Resist. The photoresist has been removed by CSX-W73 (Composition 73) at 55° C. for 20 minutes.

FIG. 9A shows a SEM observation at 500× magnification of a eutectic Pb/Sn solder bump patterned with DuPont WBR-E Dry Film Resist. The photoresist has been removed by CSX-W74 (Composition 74) at 55° C. for 20 minutes.

FIG. 9B shows a SEM observation at 500× magnification of a eutectic Pb/Sn solder bump patterned with DuPont WBR-E Dry Film Resist. The photoresist has been removed by CSX-W74 (Composition 74) at 55° C. for 20 minutes.

FIG. 10A shows an SEM observation at 500× magnification of a eutectic Pb/Sn solder bump patterned with DuPont WBR-E Dry Film Resist. The photoresist has been removed by CSX-W74B (Composition 74B) at 55° C. for 20 minutes.

FIG. 10B shows an SEM observation at 2500× magnification of a eutectic Pb/Sn solder bump patterned with DuPont WBR-E Dry Film Resist. The photoresist has been removed by CSX-W74B (Composition 74B) at 55° C. for 20, minutes.

FIG. 11A shows a SEM observation at 500× magnification of a eutectic Pb/Sn solder bump patterned with DuPont WBR-E Dry Film Resist. Under this condition, CSX-W75 (Composition 75) did not remove the photoresist and did not damage the solder bump at 55° C. for 20 minutes.

FIGS. 11B and 11C show an SEM observation of a eutectic Pb/Sn solder bump patterned with DuPont WBR-E Dry Film Resist. CSX-W75 (Composition 75) stripped the photoresist and caused damage to the solder bump at 55° C. for 40 minutes. FIG. 11C is shown at a 2500× magnification.

FIG. 12A shows a SEM observation at 500× magnification of a eutectic Pb/Sn solder bump patterned with DuPont WBR-E Dry Film Resist. Under this condition, the photoresist was completely removed by CSX-W76 (Composition 76) at 55° C. for 20 minutes.

FIG. 12B shows a SEM observation at 2500× magnification of a eutectic Pb/Sn solder bump patterned with DuPont WBR-E Dry Film Resist. Under this condition, the photoresist was completely removed by CSX-W76 (Composition 76) at 55° C. for 20 minutes

FIG. 13A shows a SEM observation at 500× magnification of a eutectic Pb/Sn solder bump patterned with DuPont WBR-E Dry Film Resist. Under this condition, the photoresist was completely removed by CSX-W77 (Composition 77) at 55° C. for 20 minutes

FIG. 13B shows a SEM observation at 2500× magnification of a eutectic Pb/Sn solder bump patterned with DuPont WBR-E Dry Film Resist. Under this condition, the photoresist was completely removed by CSX-W77 (Composition 77) at 55° C. for 20 minutes.

FIG. 14A shows an SEM observation at 2500× magnification of a eutectic Pb/Sn solder bump patterned with DuPont WBR-E Dry Film Resist. Under this condition, the photoresist was completely removed by CSX-W78 (Composition 78) at 55° C. for 20 minutes.

FIG. 14B shows an SEM observation at 2500× magnification of a eutectic Pb/Sn solder bump patterned with DuPont WBR-E Dry Film Resist. Under this condition, the photoresist was completely removed by CSX-W78 (Composition 78) at 55° C. for 20 minutes.

### DETAILED DESCRIPTION OF EMBODIMENTS

Photoresist polymer is usually difficult to dissolve in cleaning compositions, many of which contain a quaternary ammonium compound and a solvent. In most cases, the polymer, if removed at all, is lifted in large pieces and rinsed away from the substrate. The simple quaternary ammonium compound/solvent blends just do not have enough chemical activity to break down tough polymers even at elevated temperatures and prolonged contact time.

Applicants have discovered a composition for removing photoresist polymer and post etch residual from the substrate, this new composition comprising hydroxylamine (HDA®) or a hydroxylamine derivative, a quaternary ammonium compound, and at least one polar organic solvent. Such compositions result in an enhanced ability of the compound to dissolve polymer. Hydroxylamine or a hydroxylamine derivative also stabilizes the quaternary ammonium compound and thus prolongs the bath life of the compound.

The compositions of the invention show good copper compatibility and a stable bath and shelf life. The use of at least one polar organic solvent also appears to help dissolve more quaternary ammonium compound and will thus avoid the use of too much water in the system, which causes problems with metal corrosion.

The quaternary ammonium compounds of the present invention may include, but are not limited to, tetramethylammonium hydroxide (TMAH), benzyltetramethylammonium hydroxide (BTMAH), TBAH, choline hydroxide, and tris(2-hydroxyethyl)methylammonium hydroxide (THEMAH), quaternary ammonium hydroxide or mixtures thereof.

TMAH can be added to the composition as an aqueous solution, as a pentahydrate or as a solution in an organic solvent.

The hydroxylamine derivative can include, but is not limited to, N-methyl-hydroxylamine, N,N-dimethyl-hydroxylamine, N-ethyl-hydroxylamine, N,N-diethyl-hydroxylamine, methoxylamine, ethoxylamine, N-methyl-methoxylamine, and N,N diethylhydroxylamine.

The water used in the cleaning compositions of the present invention is preferably high-purity deionized water (DIW).

The polar organic solvents can include, but are not limited to, the following: a sulfone, a sulfoxide, a pyrolidone or mixtures thereof. In one embodiment of the invention, the polar organic solvent is DMSO.

In certain embodiments, the compositions of the invention can optionally contain corrosion inhibitors. In an embodiment of the invention, suitable corrosion inhibitors include, but are not limitied to, thiocarbamates (including, e.g., ammonium-diehtyldithiocarbamate), triazoles (including, e.g., benzotriazole (BTA)), phenols and hydroxyphenols (including, e.g., catechol, gallic acid, butylated hydroxytoluene (BHT), and salicylic acid), aromatic carboxylic acids (including, e.g., benzoic acid, and nitrobenzoic acid) and inorganic nitrate salts (including, e.g., ammonium, potassium, sodium and rubidium nitrate salts, aluminum nitrate and zinc nitrate).

The composition optionally contains chelating agents. Suitable chelating agents are described in commonly assigned U.S. Pat. No. 5,672,577, issued Sep. 30, 1997 to Lee, which is incorporated herein by reference. Preferred chelating agents include catechol, ethylenediaminetetraacetic acid, citric acid, pentandione and pentandione dioxime.

The composition optionally contains surfactants. Suitable surfactants include poly(vinyl alcohol), poly(ethyleneimine) and any of the surfactant compositions classified as anionic, cationic, nonionic, amphoteric, and silicone based. Preferred surfactants are poly(vinyl alcohol) and poly(ethyleneimine).

Some combinations of components require the addition of acids and/or bases to adjust the pH to an acceptable value. The acids suitable for use in the present invention are organic or inorganic. The acids can include nitric, sulfuric, phosphoric, hydrochloric acids (though hydrochloric acid can be corrosive to metals) and the organic acids, formic, acetic, propionic, n-butyric, isobutyric, benzoic, ascorbic, gluconic, malic, malonic, oxalic, succinic, tartaric, citric, or gallic acid. The last five organic acids are examples of chelating agents.

Concentrations of the acids can vary from about 1 to about 25 weight percent. The important factor is the solubility of the acid and base products with any additional agents in the aqueous solutions.

The caustic components suitable for use to adjust the pH of the cleaning solution can be composed of any common base, i.e., sodium, potassium, magnesium hydroxides, or the like. The major problem is that these bases introduce mobile ions into the final formulation. Mobile ions could destroy computer chips being produced today in the semiconductor industry. Other bases can include choline hydroxide (a quaternary amine) or ammonium hydroxide.

Additional ingredients used in the compositions of the present invention can include, for example, catechol and Dequest®-2010 (CAS No. 2809-21-4).

Operation

The method of cleaning a substrate using the cleaning compositions of the present invention involves contacting a substrate having residue thereon, particularly organometallic or metal oxide residue, with a cleaning composition of the present invention for a time and at a temperature sufficient to remove the residue. Stirring, agitation, circulation, sonication or other techniques as are known in the art optionally may be used. The substrate is generally immersed in the cleaning composition. The time and temperature are determined based on the particular material being removed from a substrate. Generally, the temperature is in the range of from about ambient or room temperature to 100° C. and the contact time is from about 30 seconds to 60 minutes. The preferred temperature and time of contact for this invention is 20 to 45° C. from 2 to 60 minutes. Generally, the substrate will be rinsed after using the composition. Preferred rinse solutions are isopropanol and DI water.

The compositions of the invention are particularly useful for removing residue from metal and via features. The compositions of the invention are particularly useful on low-k dielectrics. Low-k dielectrics are known in the art and include fluorinated silicate glass (FSG), hydrido organo siloxane polymer (HOSP), low organic siloxane polymer (LOSP), nanoporous silica (Nanoglass), hydrogen silsesquioxane (HSQ), methyl silsesquioxane (MSQ), divinysiloxane bis(benzocyclobutene) (BCB), SiLK™, poly(arylene ether) (PAE, Flare, Parylene), and fluorinated polyimide (FPI).

Table 1 lists chemicals being used in Example 1 and Examples 2.

TABLE 1

| Abbreviation | Chemical Name | Chemical Formula | CAS # | MW |
|---|---|---|---|---|
| TMAH | Tetramethylammonium hydroxide | (CH₃)₄NOH | 75-59-2 | 91.15 |
| TMAH | Tetramethylammonium hydroxide | (CH₃)₄NOH5H₂O | 10424-65-4 | 181.2 |
| Pentahydrate | Pentahydrate | | | |
| BTMAH | Benzyltetramethylammonium | C₆H₅CH₂N(OH)(CH₃)₃ | 100-85-6 | 167.3 |
| | hydroxide | | | |
| TBAH | tetrabutylammonium hydroxide | (CH₃CH₂CH₂CH₂)₄N(OH) | 2052-49-5 | 259.5 |
| Choline | 2-hydroxy-N,N,N | (CH₃)₃N(CH₂CH₂OH)(OH) | 123-41-1 | 121.2 |
| Hydroxide | trimethylethanaminium hydroxide | | | |
| THEMAH | tris(2-hydroxyethyl)methylammonium | CH₃N(CH₂CH₂OH)₃(OH) | 33667-48-0 | 181.2 |
| | hydroxide | | | |
| DGA | 2-(2-aminoethoxy)ethanol | H₂N—CH₂CH₂OCH₂CH₂OH | 929-06-6 | 105.1 |
| MEA | Monoethanolamine | NH₂CH₂CH₂OH | 141-43-5 | 61.08 |
| DQ2010 | 1-Hydroxyethylidene-1,1,- | CH₃C(OH)[PO(OH)₂] | 2809-21-4 | 206 |
| Dequest ® 2010 | diphosphonic acid | | | |
| Catechol | 1,2 Dihydroxybenzene | C₆H₄(OH)₂ | 120-80-9 | 110.1 |
| TEA | Tris(2-hydroxyethyl)amine | N(CH₂CH₂OH)₃ | 102-71-6 | 149.2 |
| PG | 1,2 Propandiol | CH₃CH(OH)CH₂OH | 57-55-6 | 76.05 |
| DMSO | Dimethyl Sulfoxide | (CH₃)₂SO | 67-68-5 | 78.13 |
| HDA ® | Hydroxylamine Freebase | H₂N—OH | 7803-49-8 | 33.03 |
| | (50% in water) | | | |
| DEHA | N,N Diethyl Hydroxylamine | HO—N(CH₂CH₃)₂ | 3710-84-7 | 89.14 |
| | (85% in water) | | | |

HDA ® is registered trademark of EKC Technology
Dequest ® is registered trademark of Thermphos International

Examples of cleaning compositions and processes according to the present invention suitable for removing photoresist polymer, including ion implanted resist, dry film resist and post etch residue from a substrate are set forth in the examples below.

Tables 2A and 2B are examples

TABLE 2A

| | | | | Solvent | | | | | | | |
|---|---|---|---|---|---|---|---|---|---|---|---|
| | Wt % | | | Wt % | | | Other | | | Contents from | |
| | Hydroxylamine | Quaternary Ammonium | | Dimethyl | | | Compound | | | starting | |
| Composition | (50%) | Compound | Wt % | Sulfoxide | Other | Wt % | Wt % | | Total | components | |
| 54 | 5.0% | TBAH (40% in | 25.0% | 70.0% | — | 0.0% | — | 0.0% | 100% | Water | 17.5% |
| | | water) | | | | | | | | | |
| 60* | 0.0% | TBAH (40% in | 30.0% | 50.0% | PG | 10.0% | TEA | 10.0% | 100% | Water | 18.0% |
| | | water) | | | | | | | | | |
| 61 | 5.0% | BTMAH (40% in | 25.0% | 70.0% | — | 0.0% | — | 0.0% | 100% | Water | 17.5% |
| | | water) | | | | | | | | | |
| 62 | 5.0% | TMAH (25% in | 25.0% | 70.0% | — | 0.0% | — | 0.0% | 100% | Water | 21.3% |
| | | water) | | | | | | | | | |
| 62B | 20.0% | TMAH | 2.5% | 77.5% | — | 0.0% | — | 0.0% | 100% | Water | 11.3% |
| | | Pentahydrate | | | | | | | | | |
| 62C | 5.0% | TMAH | 6.0% | 82.0% | Water | 7.0% | — | 0.0% | 100% | Water | 12.5% |
| | | Pentahydrate | | | | | | | | | |
| 63 | 5.0% | TMAH (7% in PG) | 25.0% | 70.0% | — | | — | 0.0% | 100% | Water | 2.5% |
| | | | | | | | | | | PG | 23.3% |
| 64 | 5.0% | TMAH (25% in | 25.0% | 60.0% | — | | TEA | 10% | 100% | Water | 21.3% |
| | | water) | | | | | | | | | |
| 65 | 5.0% | TMAH (25% in | 25.0% | 60.0% | PG | 5.0% | TEA | 5% | 100% | Water | 21.3% |
| | | water) | | | | | | | | | |
| 66 | 5.0% | TMAH (25% in | 25.0% | 55.0% | PG | 10.0% | TEA | 5% | 100% | Water | 21.3% |
| | | water) | | | | | | | | | |
| 67 | 5.0% | TMAH (25% in | 25.0% | 60.0% | PG | 10.0% | — | 0.0% | 100% | Water | 21.3% |
| | | water) | | | | | | | | | |
| 68 | 5.0% | TBAH (40%) | 25.0% | 60.0% | PG | 10.0% | | | 100% | Water | 17.5% |
| 69* | 0.0% | TMAH (25% in | 20.0% | 60.0% | — | 0.0% | — | 0.0% | 100% | Water | 15.0% |
| | | water) | | | | | | | | | |
| | | TMAH (7% in PG) | 20.0% | | | | | | | PG | 18.6% |

*Does not contain hydroxylamine (HDA ®)

TABLE 2B

| | | | | Solvent | | | | | | | |
|---|---|---|---|---|---|---|---|---|---|---|---|
| | Wt % | | | Wt % | | | | | | Contents from | |
| | Hydroxylamine | Quaternary Ammonium | | Dimethyl | | | Other Compound | | | starting | |
| Composition | (50%) | Compound | Wt % | Sulfoxide | Other | Wt % | Wt % | | Total | components | |
| 70 | 4.8% | TMAH (25% in water) | 23.7% | 66.7% | — | 0.0% | DQ-2010 | 4.80% | 100% | Water | 22.1% |
| | | | | | | | (60% in water) | | | | |
| 71-0 | 10.0 | TMAH (25% in water) | 17.0% | 73.0% | | 0.0% | — | 0.0% | 100% | Water | 17.8% |
| 71-1 | 10.0% | TMAH (25% in water) | 16.8% | 72.3% | — | 0.0% | Catechol | 1% | 100% | Water | 17.6% |
| 71-2 | 9.8% | TMAH (25% in water) | 16.7% | 71.6% | | 0.0% | Catechol | 2% | 100% | Water | 17.4% |
| 72 | 5.0% | TMAH (25% in | 25.0% | 70.0% | — | 0.0% | — | 0.0% | 100% | Water | 2.5% |
| | | Methanol) | | | | | | | | Methanol | 18.8% |
| 73 | 5.0% | TMAH (25% in water) | 12.5% | 70.0% | — | 0.0% | — | 0.0% | 100% | Water | 9.4% |
| | | TMAH (25% in | 12.5% | | | 0.0% | | | | Methanol | 9.4% |
| | | Methanol) | | | | | | | | | |
| 74 | 5.0% | TMAH Pentahydrate | 2.5% | 85.0% | — | 0.0% | DGA | 7.50% | 100% | Water | 3.8% |
| 74B | 5.0% | TMAH Pentahydrate | 5.0% | 75.0% | — | 0.0% | DGA | 15% | 100% | Water | 5.0% |
| 75 | 5.0% | TMAH (15% in PG) | 30.0% | 65.0% | — | 0.0% | — | 0.0% | 100% | Water | 2.5% |
| | | | | | | | | | | PG | 25.5% |
| 76 | 5.0% | TMAH Pentahydrate | 2.5% | 85.0% | — | 0.0% | MEA | 7.50% | 100% | Water | 3.8% |
| 77* | 0.0% | TMAH Pentahydrate | 5.0% | 65.0% | Water | 5.0% | DGA | 25% | 100% | Water | 7.5% |
| 78 | 5.0% | TMAH Pentahydrate | 6.0% | 72.0% | Water | 7.0% | — | 0.0% | 100% | Water | 12.5% |
| | | TMAH (15% in PG) | 10.0% | | | | | | | PG | 8.5% |
| EKC108 | 5.0% | Choline Hydroxide | 25.0% | 70.0% | — | 0.0% | — | 0.0% | 100% | | 15.0% |

*Does not contain hydroxylamine (HDA ®)

TABLE 3A

| | | Cu | | |
|---|---|---|---|---|
| | Bath Life | Loss | Coral Loss | |
| Composition | (hr) | (Å) | (Å) | Comments |
| 54 | 0 | 20 | −134 | 1. No significant Cu and Coral etch change over 96 hours of bath life. |
| | 24 | 38 | — | 2. Strips photoresist (PR) wafers well. |
| | 72 | −2 | — | 3. Slowly dissolves WBR-E dry film photoresist. |
| | 96 | −19 | −122 | |
| 61 | 0 | 22 | 850 | 1. No Cu etch change over 24 hours. |
| | 24 | 23 | | 2. The presence of BTMAH appears to cause high low K etch rate. |
| | | | | 3. BTMAH appears to cause high Poly Si etch rate (1000 Å/10 min). |
| 62 | 0 | 8 | 27 | 1. No significant Cu and low k etch rate change over |
| | 24 | 16 | −9 | 120 hours. |
| | 48 | 49 | | 2. Strips JSR HM8005 and Asahi dry film resists |
| | 120 | 42 | 0 | 3. StripS unprocessed DuPont WBR-E and Asahi dry film resist in less than |
| | | | | 30 minutes at 55° C. |
| | | | | 4. Dissolves unprocessed WBR-E dry film less than 30 min. at 55° C. |
| | | | | 5. AttackS Pb/Sn solder bumps |
| 62B | 0 | 39 | | 1. Forms a lot of bubbles in the stripping bath. |
| | | | | 2. Slow dry film stripping vs. COMPOSITION 62. |
| | | | | 3. No Pb/Sn attack. |
| | | | | 4. Al Etch: 67.8 Å/min. |
| 62C | 0 | 30 | | 1. Complete dissolves WBR120E dry film |
| | 24 | 12 | | 2. Strips DF fast, 3:10/7:30 min (blue color fade and DF complete dissolve |
| | 48 | 33 | | time) |
| | 120 | −8 | | 3. Stable copper etch rate |
| | | | | 4. No PbSn attack |
| | | | | 5. Al etch: 46.4 Å/min |

TABLE 3B

| | Bath Life | Cu Loss | Coral Loss | |
|---|---|---|---|---|
| Composition | (hr) | (Å) | (Å) | Comments |
| 63 | 2 | −2 | −173 | 1. Doesn't strip photoresist |
| | | | | 2. Not enough TMAH. |
| | | | | 3. Process Condition: 55° C./30 min |
| 64 | 0 | 15 | −63 | 1. Cu etch rate was observed.after 24 hours at elevated temperature |
| | 24 | 39 | −75 | 2. TEA might cause TMAH decomposition. |
| | 48 | 142 | −132 | 3. TEA helps dissolving WBR-E. |
| | 72 | 271 | −87 | 4. Si etch rate is high. |
| | 144 | 705 | −62 | |
| 65 | 0 | 24 | −79 | 1. Si etch rate is high. |
| 66 | 0 | 15 | −95 | 1. Si etch rate is high. |
| | | | | 2. Dissolves WBR-E. |
| 67 | 0 | 5 | −107 | 1. After 96 hours of heating, an increased Cu etch rate was observed. |
| | 24 | 61 | | 2. Dissolves WBR-E. |
| | 96 | 339 | | 3. Si etch rate is low 5 Å/30 min. |
| 68 | 0 | 4 | −119 | 1. After 96 hours of heating, no Cu etch rate change was observed. |
| | 24 | 36 | | 2. Dissolves WBR-E. |
| | 96 | 23 | −177 | 3. Etches Si. |
| 74 | 0 | 4 | | 1. Pb/Sn bump looks good. |
| | 0 | −3 | | 2. High dry film stripping chemistry. |
| | 72 | 314 | | 3. WRB-E dry film completely dissolved |
| | | | | 4. Unstable copper etch rate etch. Cu etch rate increased in 72 hours. |

TABLE 3C

| | Bath Life | Cu Loss | Coral Loss | |
|---|---|---|---|---|
| Composition | (hr) | (Å) | (Å) | Comments |
| 74B | 0 | 19 | | 1. Pb/Sn bump looks good. |
| | 72 | 612 | | 2. WRB-E dry film completely dissolved |
| | | | | 3. Cu etch rate increased in 72 hours. |
| 75 | 0 | 15 | | 1. Pb/Sn bump looks good, photoresist partially dissolved in 20 min. |
| | 72 | −9 | | 2. Photoresist completely removed with extended process (40 min); however, pin |
| | | | | hole on bump was observed. |
| | | | | 3. WRB-E dry film stripping is slow, partially dissolved in 20 min. |
| | | | | 4. Stable copper etch rate. No change of Cu etch rate in 72 hours. |
| 76 | 0 | 2 | | 1. Pb/Sn bump looks good, still have some photoresist left after 20 min. |
| | 72 | 908 | | 2. Stripping WRB-E DRY FILM is slow; complete dissolved in 17 min. |
| | | | | 3. Unstable copper etch rate. Cu etch rate increases in 72 hours. |
| 78 | 0 | 13 | | 1. Pb/Sn bump looks better than COMPOSITION 62 and worse than CSX-W62 |
| | 24 | 26 | | 2. Completely dissolves WBR120E dry film. |
| | 96 | 83 | | 3. Slight increases of copper etch rate in 96hours. |

The study results are summarized in Table 3A, 3B and 3C, and illustrate the compatibility of the said compositions with copper surfaces and low k dielectric surfaces, such as Coral® from Novellus System Inc., after the said composition has been maintained at 55° C. for 24, 72 and 96 hours in bath life and shelf life studies.

The lower molecular weight of the quaternary ammonium hydroxide used in the R₄NOH/HDA®/DMSO blend might have a higher dissolution rate of WBR-E dry film resist from DuPont.
Composition 54, which contains TBAH: (CH₃CH₂CH₂CH₂)₄N(OH)
Composition 61, which contains BTMAH: C₆H₅CH₂N(OH)(CH₃)₃
Composition 62, which contains TMAH: (CH₃)₄N(OH).

In accordance with the above, one sees the following stripping power sequence:

| Composition 62 | | EKC108 | | Composition 54 |
|---|---|---|---|---|
| TMAH | = | Choline hydroxide | > | TBAH |
| MW91 | | MW 121 | | MW259 |

The addition of an —OH group to R₄NOH/HDA®/DMSO and R₄NOH/DMSO blends might improve WBR-E dissolution. This hypothesis has been supported by the formulations listed below. However, some ROH compounds will cause a Cu. etch rate change and etch Si:
Composition 64 (addition of 10% TEA to COMPOSITION 54 blend) showed better dissolution when compared with COMPOSITION 54
Composition 68 (addition of 10% PG to COMPOSITION 54 blend) showed better dissolution when compared with COMPOSITION 54
EKC108 and Composition 22 (quaternary ammonium hydroxide with —CH₂CH₂OH group) dissolve better than Composition 54 (contains (CH₃CH₂CH₂CH₂)₄NOH))

Composition 62 appears to be a good candidate for WBR-E dry film removal in terms of photoresist dissolution, Cu and Si compatibility and stable bath life. The following observations are also noted with respect to COMPOSITION 62:
The Pb/Sn etch appears higher than that using EKC108.
The use of Composition 62 creates bubbles during the PHOTORESIST stripping process (same as EKC108). Defoamer may be required if processed dry film resist contains surfactants that will cause forming.
   The study results follow:

The following observations result from testing:

Compositions 60, 69 and 77, which do not contain hydroxylamine, lack the stripping capability of the photoresist

The water content in the HDA®/TMAH/DMSO blend is the main contributor to Pb/Sn bump attack. (Compare SEM summary of compositions 62, -W72 and -W73).

The addition of DQ2010 in the system does not appear to reduce the Pb/Sn attack level.

The addition of DGA or MEA in the HDA®/TMAH/DMSO system appears to enhance the stripping power of the dry film resist.

The addition of catechol in the system helps control the Al etch.

The addition of propylene glycol in the system helps dissolve more TMAH. Composition 62C appears to be a promising candidate for dry film removal application in terms of polymer dissolution, good compatibility with under bump metallurgy (UBM) (especially copper) and various bumps.

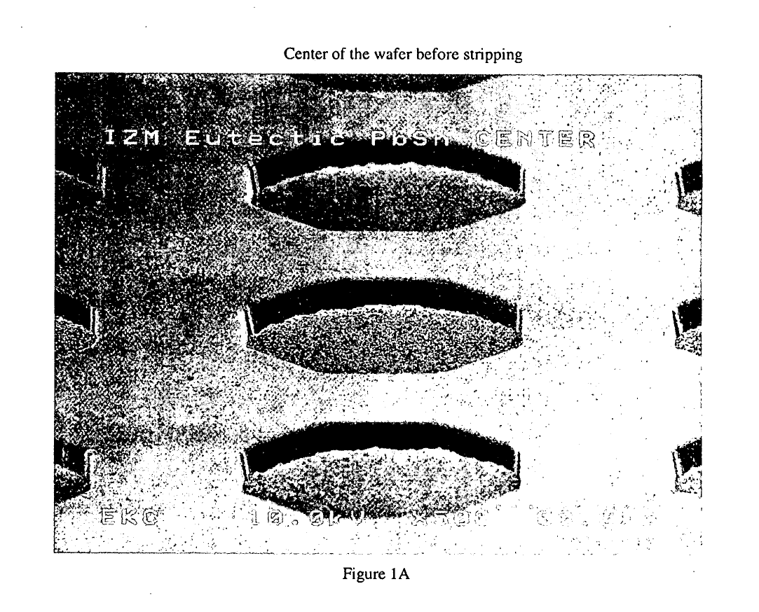

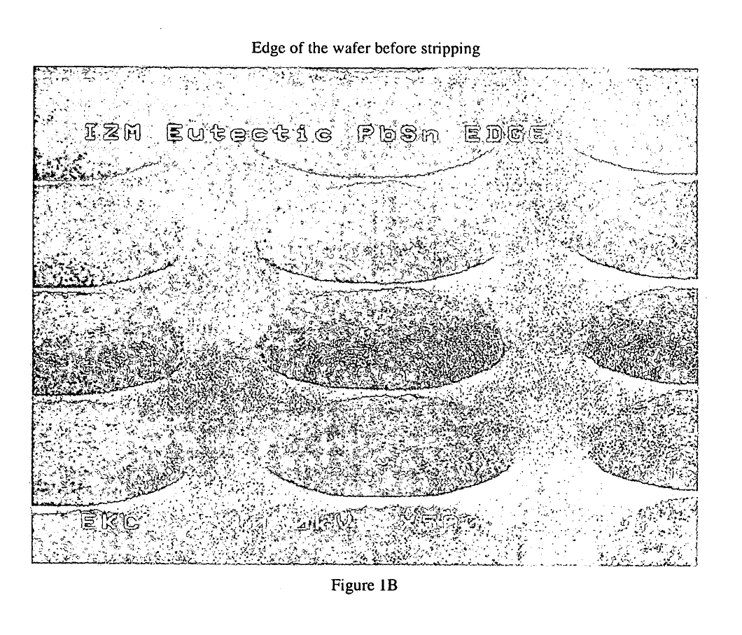

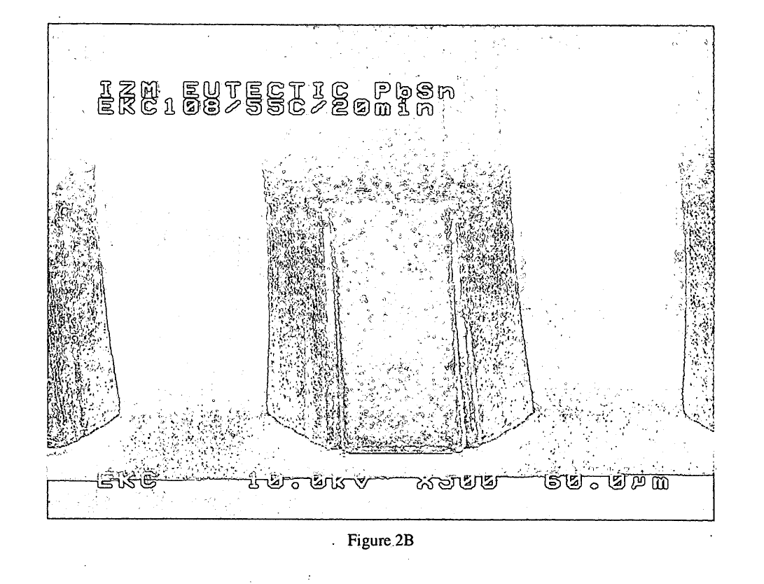

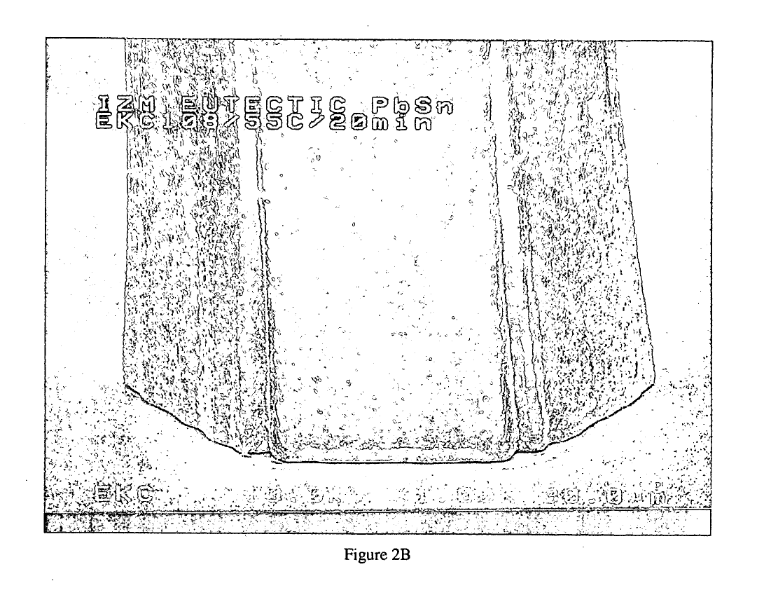

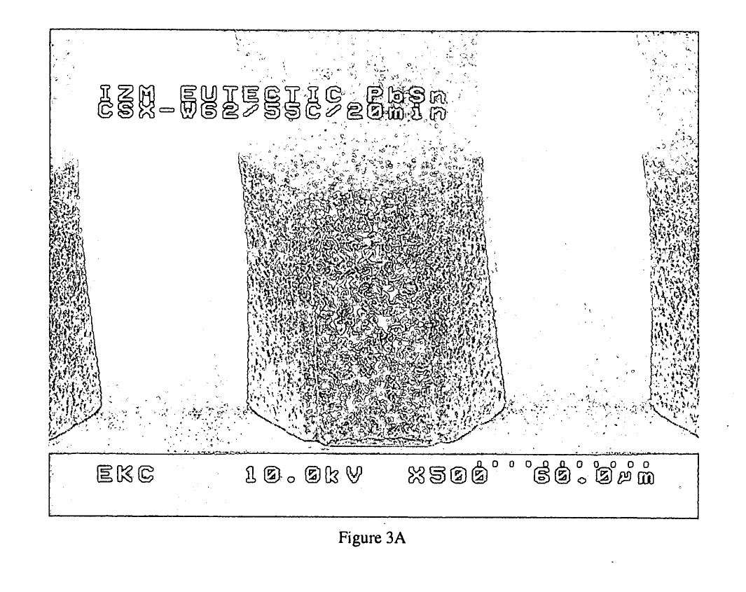

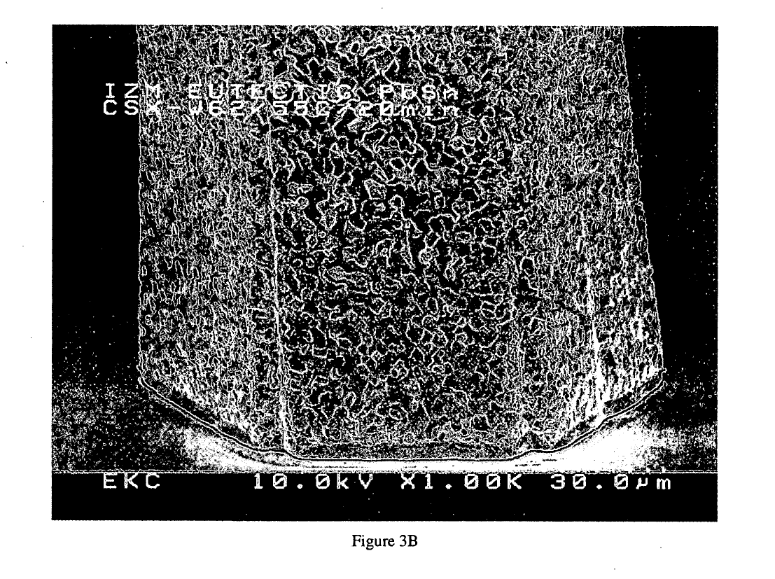

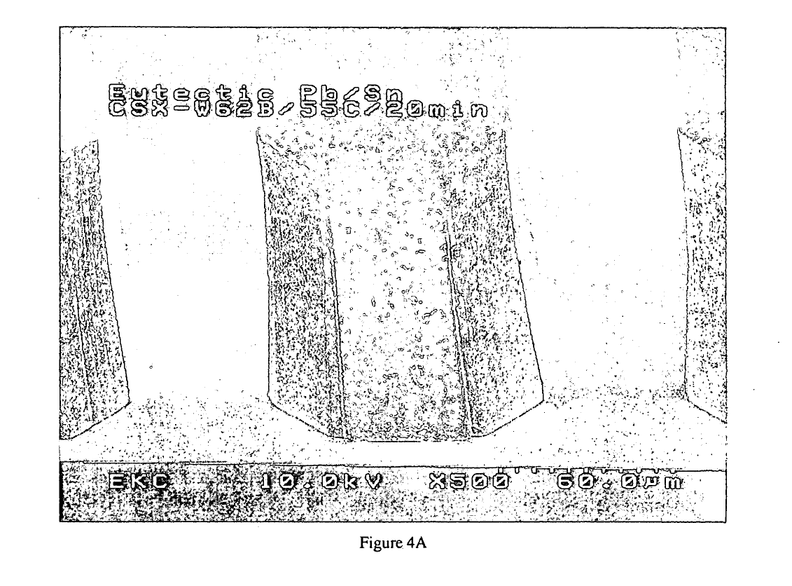

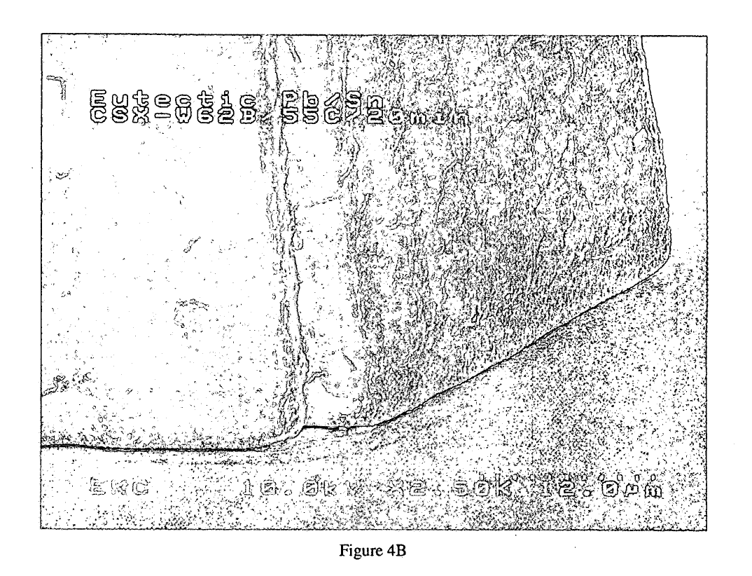

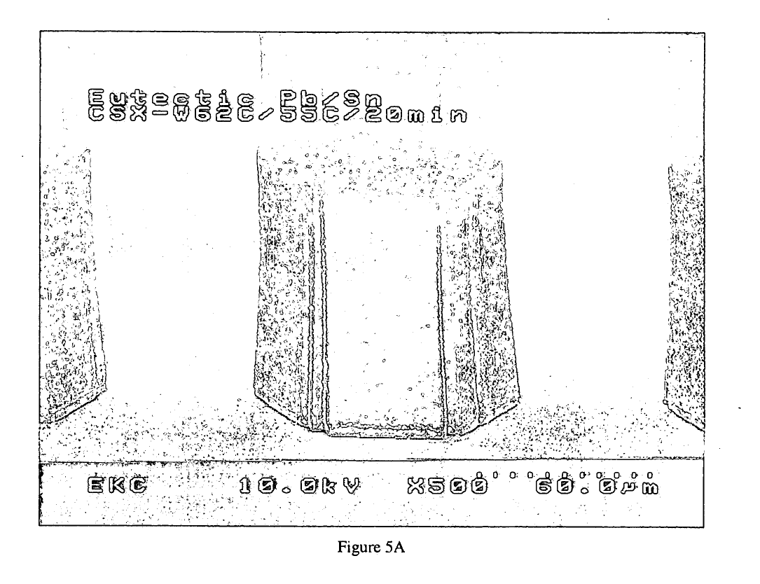

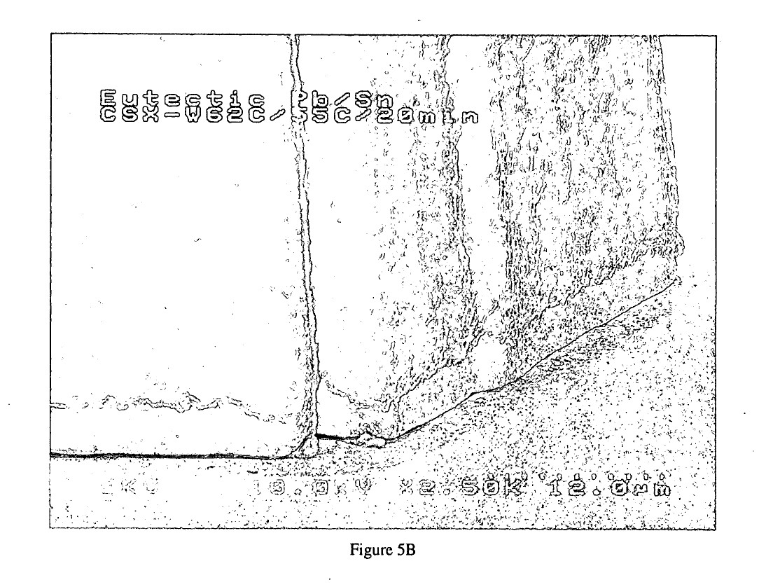

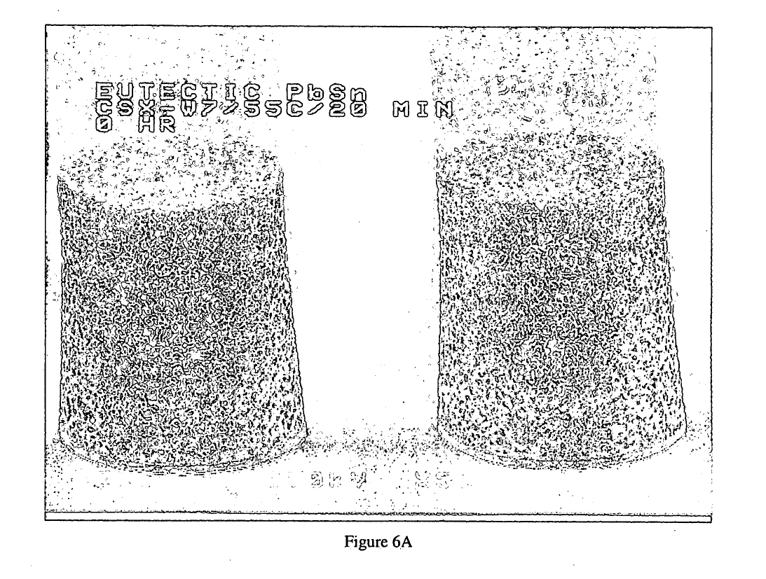

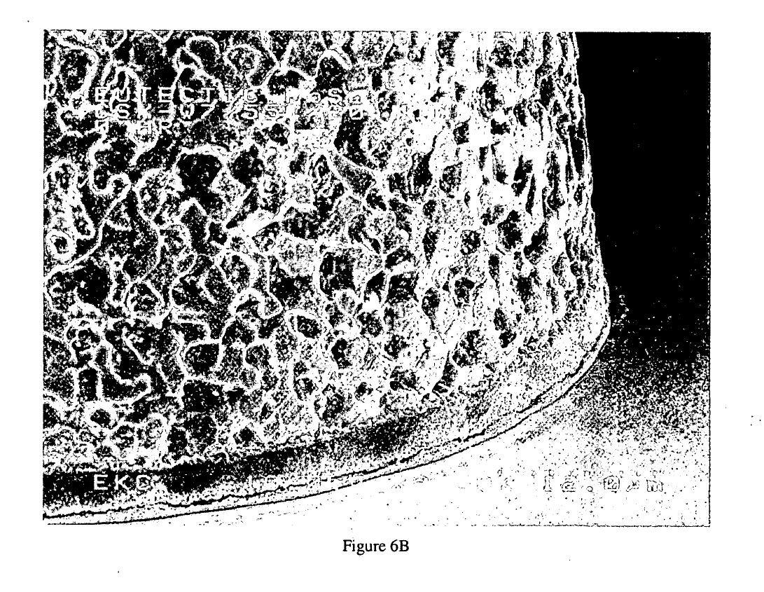

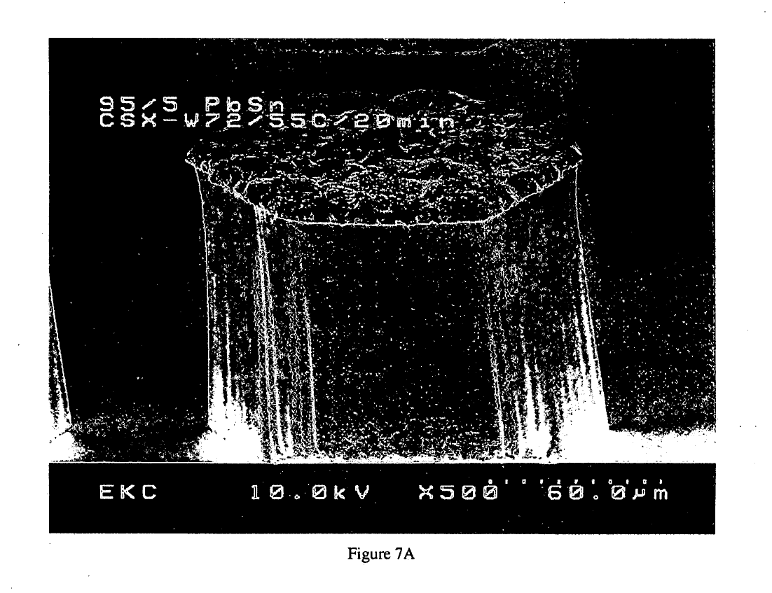

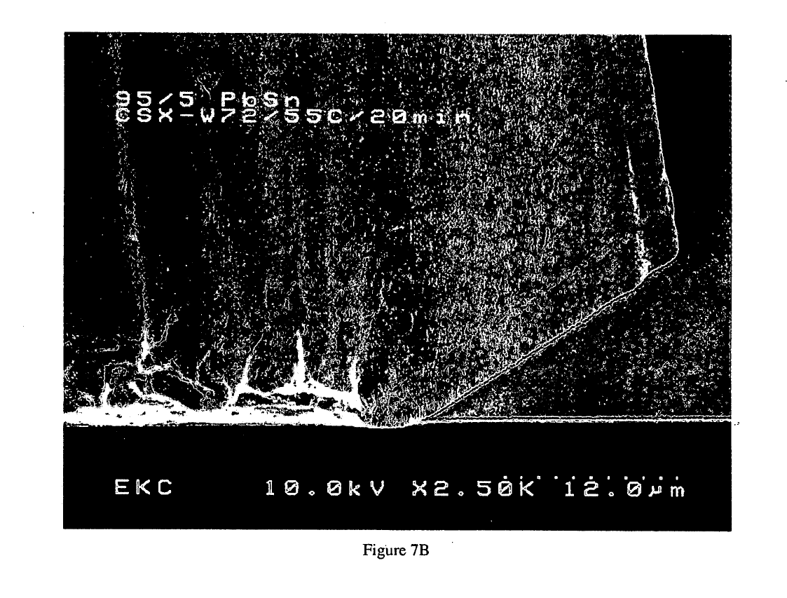

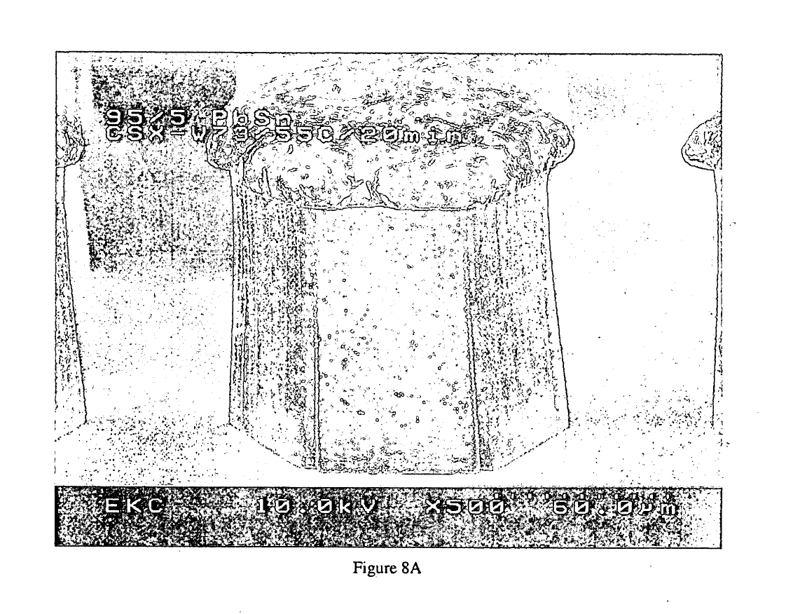

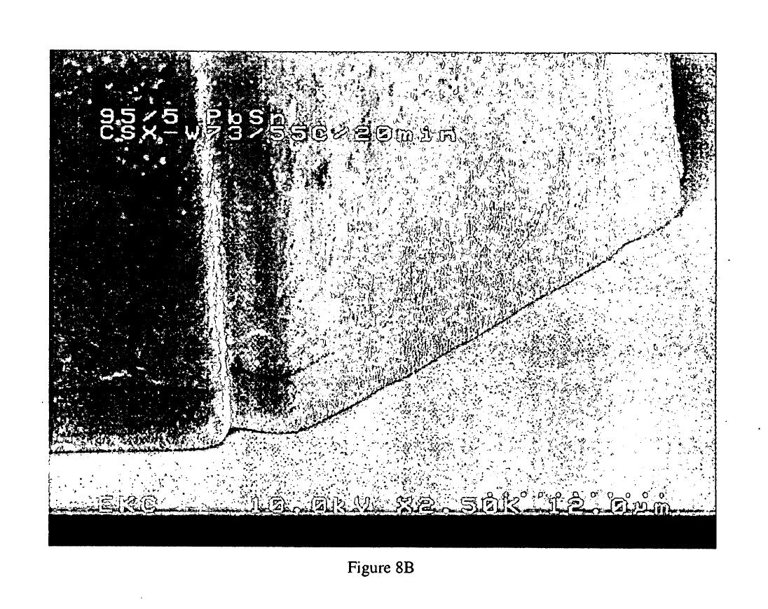

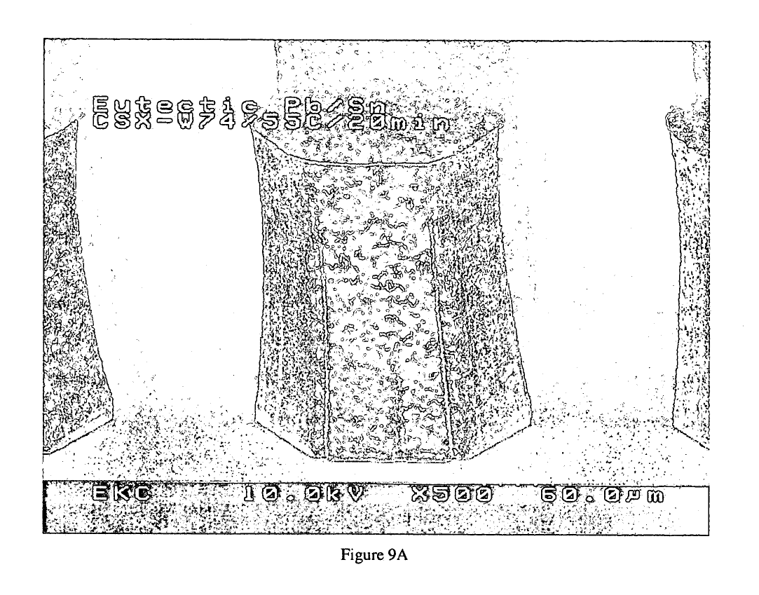

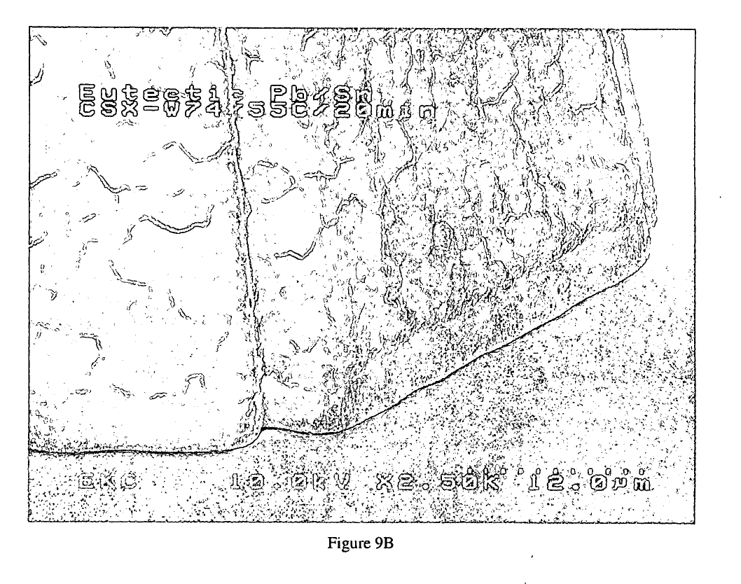

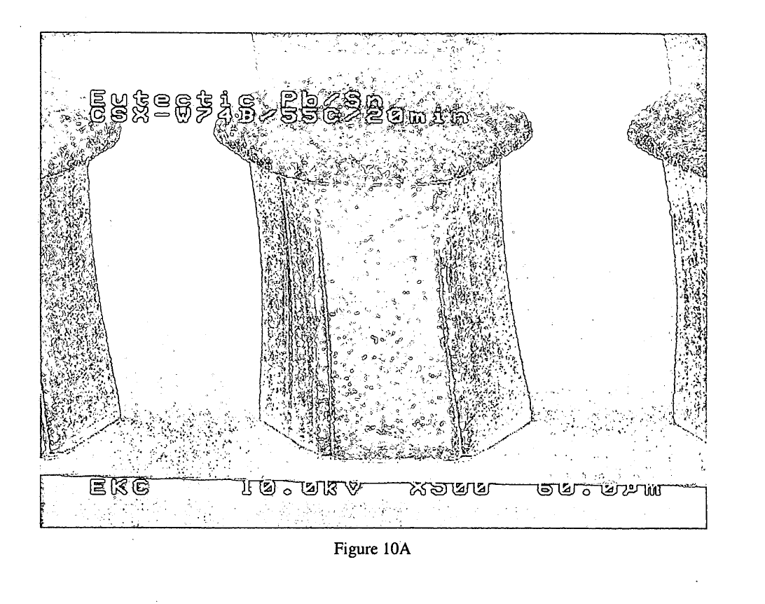

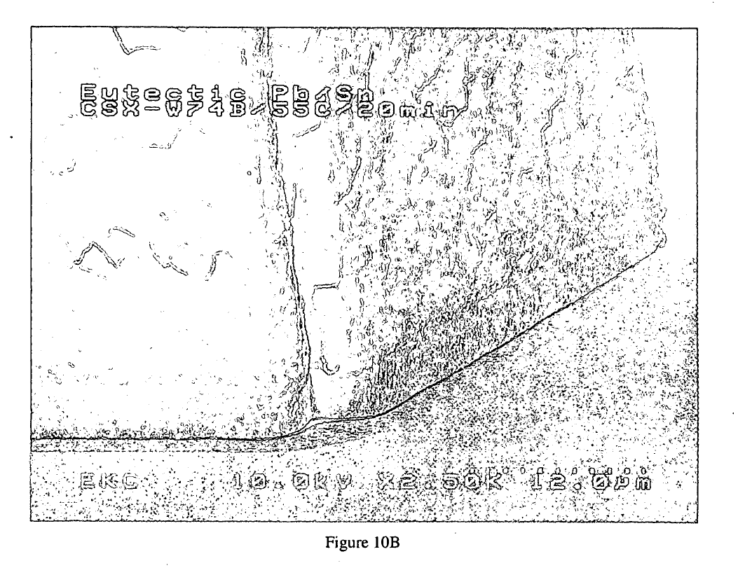

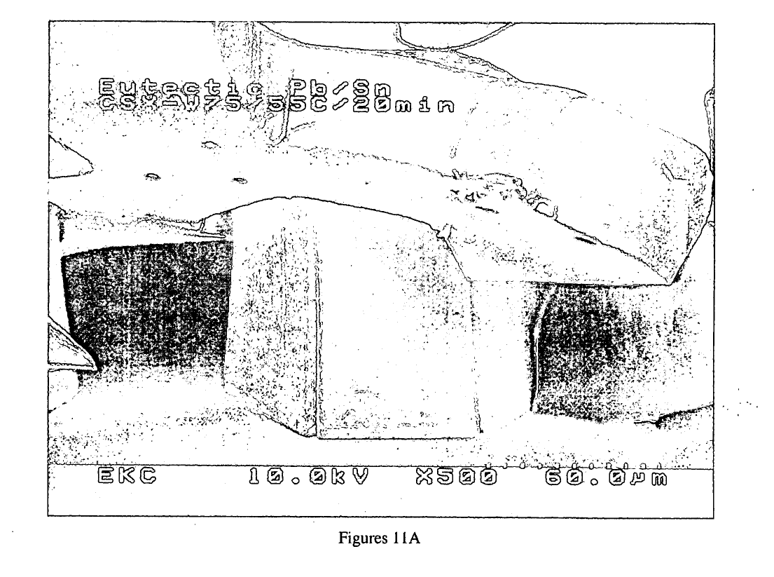

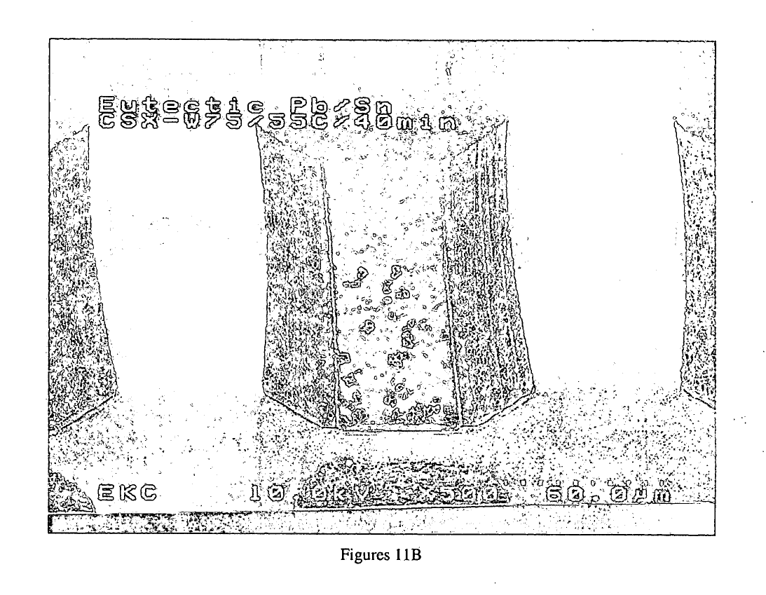

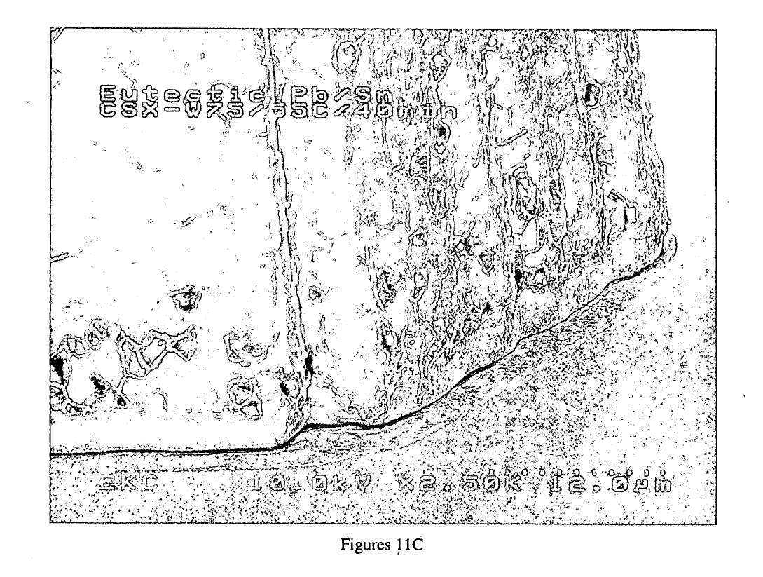

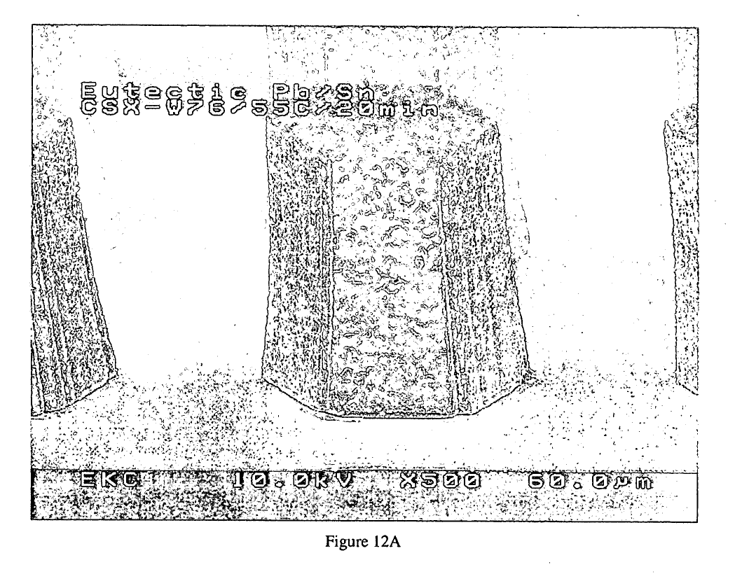

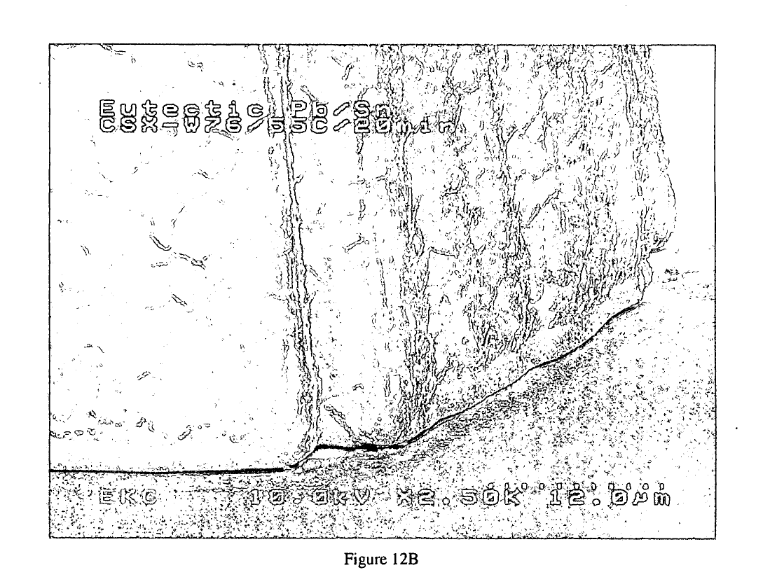

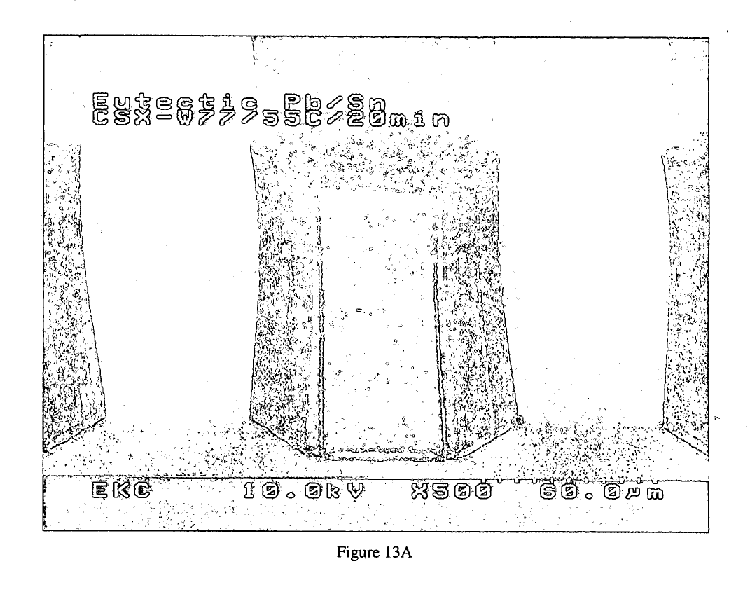

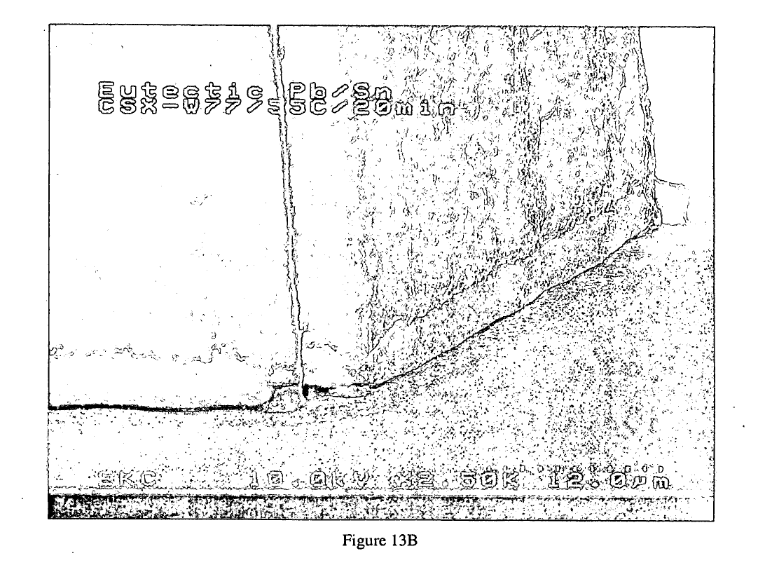

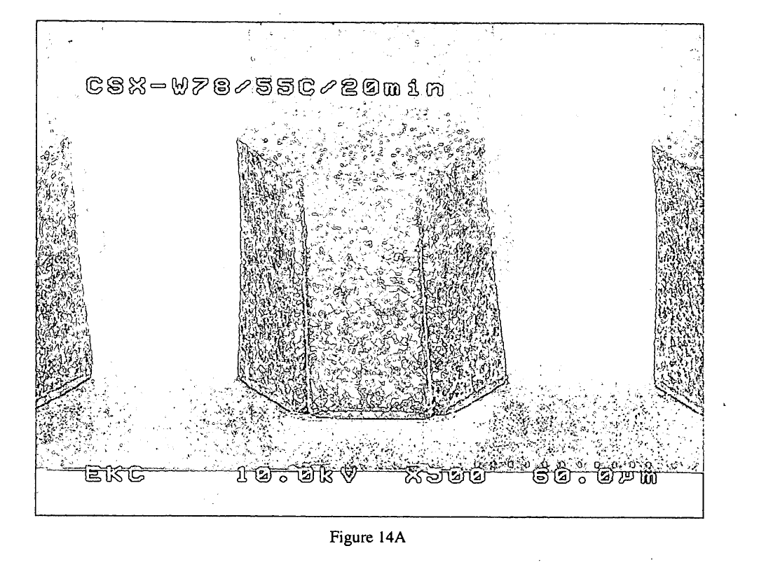

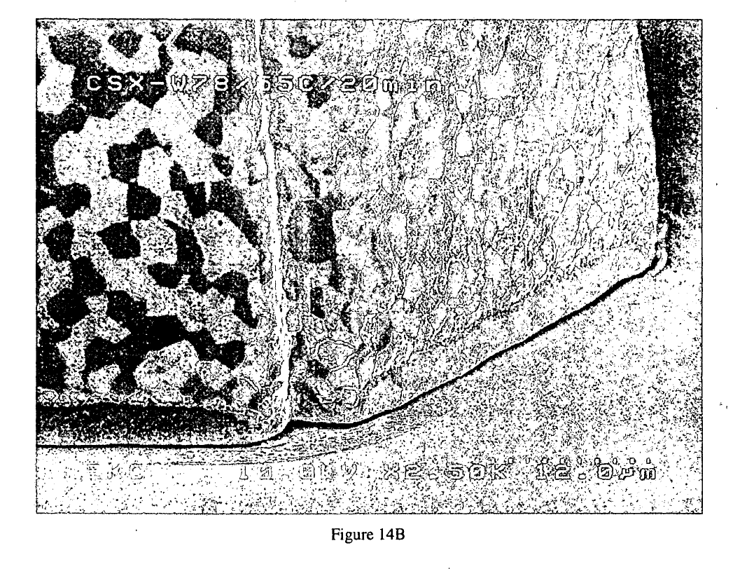

FIGS. 1A to 14B are SEM observation on resist stripping performance with WBR-E dry film resist from DuPont and compatibility with eutectic Pb/Sn solder bump. These samples were prepared at Fraunhofer IZM Berlin, Germany.

The invention has been illustrated by the embodiments described above, but is not intended to be limited to those embodiments.

Having described the invention in detail, those skilled in the art will appreciate that, given the present disclosure modifications may be made to the invention without departing from the spirit of the inventive concept described herein. Therefore, it is not intended that the scope of the invention be limited to the specific embodiments illustrated and described.

What is claimed is:

1. A composition for removing undesired matter from a substrate, the composition comprising: hydroxylamine or a hydroxylamine derivative, a quaternary ammonium compound and at least one polar organic solvent,
wherein the quaternary ammonium compound is selected from the group consisting of tetramethylammonium hydroxide (TMAH), benzyltetramethylammonium hydroxide (BTMAH), tetrabutylammonium hydroxide (TBAH), choline hydroxide, and tris(2-hydroxyethyl)methylammonium hydroxide (THEMAH), quaternary ammonium hydroxide and mixtures thereof.

2. The composition of claim 1, wherein the quaternary ammonium compound is TMAH.

3. The composition of claim 2, wherein the hydroxylamine or hydroxylamine derivative is hydroxylamine and the at least one polar organic solvent comprises DMSO.

4. The composition of claim 1, wherein the hydroxylamine or a hydroxylamine derivative is N,N diethyl hydroxylamine.

5. The composition of claim 1, further comprising a corrosion inhibitor.

6. The composition of claim 1, wherein the undesired matter comprises polyimide, cured polyimide, epoxy photoresist, hardened photoresist, liquid or dry film resist, ion implanted photoresist or other polymers from a substrate comprising metal and/or metal alloy portions and/or layers.

7. The composition of claim 1, wherein the undesired matter is photoresist in wafer level packaging or solder bumping applications.

8. The composition of claim 6, wherein the metal and/or metal alloy comprises copper, aluminum, lead, silver, tin, lead/tin, or Ni.

9. The composition of claim 6, wherein the metal and/or metal alloy comprises one or more solder bumps.

10. The composition of claim 1 comprising: from about 1 to about 10% by weight of the hydroxylamine or hydroxylamine derivative, from about 10 to about 30% by weight of the quaternary ammonium compound and from about 50 to about 85% by weight of the, at least one polar organic solvent,
wherein the hydroxylamine or hydroxylamine derivative is present in about 50% in water, and
wherein the quaternary ammonium compound is present in about 25% in water.

11. The composition of claim 10, wherein the hydroxylamine or hydroxylamine derivative is hydroxylamine, the quaternary ammonium compound is TMAH and the at least one polar organic solvent comprises DMSO.

12. A process for removing undesired matter from a substrate, said process comprising contacting said substrate with the composition of claim 1 for a period of time and at a temperature sufficient to remove the undesired matter from the substrate.

13. The process of claim 12, wherein the undesired matter is photoresist in wafer level packaging or solder bumping applications.

14. The process of claim 12, wherein the undesired matter is polyimide, cured polyimide, epoxy photoresist, hardened photoresist, liquid or dry film resist, ion implanted photoresist or other polymers from a substrate comprising metal and/or metal alloy portions and/or layers.

15. A process for removing undesired matter from a substrate, said process comprising contacting said substrate with the composition of claim 10 for a period of time and at a temperature sufficient to remove the undesired matter from the substrate.
